(19) United States
(12) Patent Application Publication
(10) Pub. No.: US 2026/0331015 A1
(43) Pub. Date: Oct. 22, 2026

(54) DISPLAY DEVICE AND ELECTRONIC DEVICE INCLUDING THE SAME

(71) Applicant: Samsung Display Co., Ltd., Yongin-si (KR)

(72) Inventor: YONGGU KIM, Yongin-si (KR)

(21) Appl. No.: 19/444,727

(22) Filed: Jan. 9, 2026

(30) Foreign Application Priority Data
Apr. 21, 2025 (KR) 10-2025-0051321

(51) Int. Cl. G09G 3/20

(52) U.S. Cl. CPC G09G 3/20; G09G 2320/041; G09G 2330/028

(57) ABSTRACT

A display device includes a display panel configured to display an image, a display panel driver configured to drive the display panel, a thermoelectric element located on a first surface of the display panel and which overlaps the display panel driver and an energy converting block configured to generate an electric energy based on a temperature difference of the thermoelectric element. The energy converting block determines a first voltage corresponding to the temperature difference of the thermoelectric element. The energy converting block outputs generation voltage data corresponding to the first voltage. The display panel driver generates a data voltage which is applied to the display panel based on the generation voltage data.

This application claims priority to Korean Patent Application No. 10-2025-0051321, filed on Apr. 21, 2025 and all the benefits accruing therefrom under 35 U.S.C. § 119, the content of which in its entirety is herein incorporated by reference.

### BACKGROUND

### 1. Field

Embodiments of the present invention relate to a display device and an electronic device including the same. More particularly, embodiments of the present invention relate to a display device compensating a temperature change and an electronic device including the same.

### 2. Description of the Related Art

Generally, a display device includes a display panel and a display panel driver. The display panel includes a plurality of gate lines, a plurality of data lines, a plurality of emission lines and a plurality of pixels. The display panel driver includes a gate driver providing a gate signal to the gate lines, a data driver providing a data voltage to the data lines, an emission driver providing an emission signal to the emission lines and a driving controller controlling the gate driver, the data driver and the emission driver.

Generally, a display quality is deteriorated based on a temperature change of the display device.

### SUMMARY

Embodiments of the present invention provide a display device in which a display quality is improved.

Embodiments of the present invention provide an electronic device in which a display quality is improved.

According to embodiments, a display device includes a display panel configured to display an image, a display panel driver configured to drive the display panel, a thermoelectric element located on a first surface of the display panel and which overlaps the display panel driver and an energy converting block configured to generate an electric energy based on a temperature difference of the thermoelectric element. The energy converting block determines a first voltage corresponding to the temperature difference of the thermoelectric element. The energy converting block outputs generation voltage data corresponding to the first voltage. The display panel driver generates a data voltage which is applied to the display panel based on the generation voltage data.

In an embodiment, the data voltage may be generated based on a generation voltage offset voltage. The generation voltage offset voltage may be determined based on a voltage level difference between the first voltage and a reference voltage.

In an embodiment, the generation voltage offset voltage may be determined based on a generation voltage lookup table. Each of the generation voltage offset voltage and the voltage level difference may be provided in plurality, The generation voltage lookup table may include the voltage level differences and the generation voltage offset voltages corresponding to the voltage level differences, respectively.

In an embodiment, the data voltage may be generated based on a final offset voltage based on both a state offset voltage corresponding to a state information of the display panel and the generation voltage offset voltage.

In an embodiment, the state information may include a setting brightness of the display panel, a driving frequency of the display panel or a deterioration information of the display panel.

In an embodiment, the final offset voltage may be calculated based on a following first equation:

FVOFF=aX1+bX2+c. The first equation

Herein, FVOFF refers to the final offset voltage, a refers to a first constant, X1 refers to the state offset voltage, b refers to a second constant, X2 refers to the generation voltage offset voltage and c refers to a third constant.

In an embodiment, the final offset voltage may be calculated based on a following second equation:

FVOFF=aX1²+bX2+c. The second equation

Herein, FVOFF refers to the final offset voltage, a refers to a first constant, X1 refers to the state offset voltage, b refers to a second constant, X2 refers to the generation voltage offset voltage and c refers to a third constant.

In an embodiment, the final offset voltage may be calculated based on a following third equation:

FVOFF=aX1+bX2²+c. The third equation

Herein, FVOFF refers to the final offset voltage, a refers to a first constant, X1 refers to the state offset voltage, b refers to a second constant, X2 refers to the generation voltage offset voltage and c refers to a third constant.

In an embodiment, the final offset voltage may be calculated based on a following fourth equation:

FVOFF=aX1²+bX2²+c. The fourth equation

Herein, FVOFF refers to the final offset voltage, a refers to a first constant, X1 refers to the state offset voltage, b refers to a second constant, X2 refers to the generation voltage offset voltage and c refers to a third constant.

In an embodiment, the reference voltage may be changed based on an environmental fact.

In an embodiment, the first voltage may be determined based on a Seeback effect of the thermoelectric element.

According to embodiments, a display device includes a display panel configured to display an image, a display panel driver configured to drive the display panel, a thermoelectric element configured to control a temperature of the display panel and an energy converting block configured to determine a generation voltage corresponding to the temperature of the display panel. The energy converting block outputs generation voltage data corresponding to the generation voltage. The display panel driver generates a data voltage which is applied to the display panel based on the generation voltage data.

In an embodiment, the generation voltage may be determined based on a Seeback effect of the thermoelectric element.

In an embodiment, the data voltage may be generated based on a generation voltage offset voltage. The generation voltage offset voltage may be determined based on a voltage level difference between the generation voltage and a reference voltage.

In an embodiment, the data voltage may be generated based on a final offset voltage based on both a state offset voltage corresponding to a state information of the display panel and the generation voltage offset voltage.

In an embodiment, the state information may include a setting brightness of the display panel, a driving frequency of the display panel or a deterioration information of the display panel.

According to embodiments, an electronic device includes a display panel configured to display an image, a display panel driver configured to drive the display panel based on an input control signal, a processor configured to output the input control signal, a thermoelectric element located on a first surface of the display panel and which overlaps the display panel driver and an energy converting block configured to generate an electric energy based on a temperature difference of the thermoelectric element. The energy converting block determines a first voltage corresponding to the temperature difference of the thermoelectric element. The energy converting block outputs generation voltage data corresponding to the first voltage. The display panel driver generates a data voltage which is applied to the display panel based on the generation voltage data.

In an embodiment, the data voltage may be generated based on a generation voltage offset voltage. The generation voltage offset voltage may be determined based on a voltage level difference between the first voltage and a reference voltage.

In an embodiment, the data voltage may be generated based on a final offset voltage based on both a state offset voltage corresponding to a state information of the display panel and the generation voltage offset voltage.

In an embodiment, the first voltage may be determined based on a Seeback effect of the thermoelectric element.

As described above, a display panel may display an image based on a data voltage. A generation voltage offset voltage may be considered in the data voltage outputted by a display panel driver. The generation voltage offset voltage may be determined based on the generation voltage. Additionally, the generation voltage may be generated based on a temperature difference of a thermoelectric element. The temperature difference of the thermoelectric element may be generated based on a temperature change of the display panel driver. Accordingly, a temperature change of the display panel driver may be considered in the data voltage. Since a temperature change of the display panel driver may be considered in the data voltage, the display quality of the display panel may be effectively improved.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to embodiments of the present invention.

FIG. 2 is a side view illustrating an example of the display device of FIG. 1.

FIG. 3 is an enlarged view of area A of FIG. 2.

FIG. 4 is a plan view illustrating an example of the display device of FIG. 1.

FIG. 5 is a diagram illustrating an example of a heat pipe included in the display device of FIG. 2.

FIG. 6 is a diagram illustrating an energy flow of a display device of FIG. 2.

FIG. 7 is a block diagram illustrating an example of a display panel driver, an energy converting block and an embedded battery included in the display device of FIG. 2.

FIG. 8 is a table illustrating an example of a generation voltage lookup table stored in a display panel driver of FIG. 7.

FIG. 9 is a flowchart illustrating an example of a method by which the display panel driver of FIG. 7 generates a data voltage.

FIG. 10 is a block diagram illustrating an electronic device according to embodiments of the present invention.

FIG. 11 to FIG. 13 are schematic diagrams illustrating an electronic device according to embodiments.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present. Hereinafter, the present invention will be explained in detail with reference to the accompanying drawings.

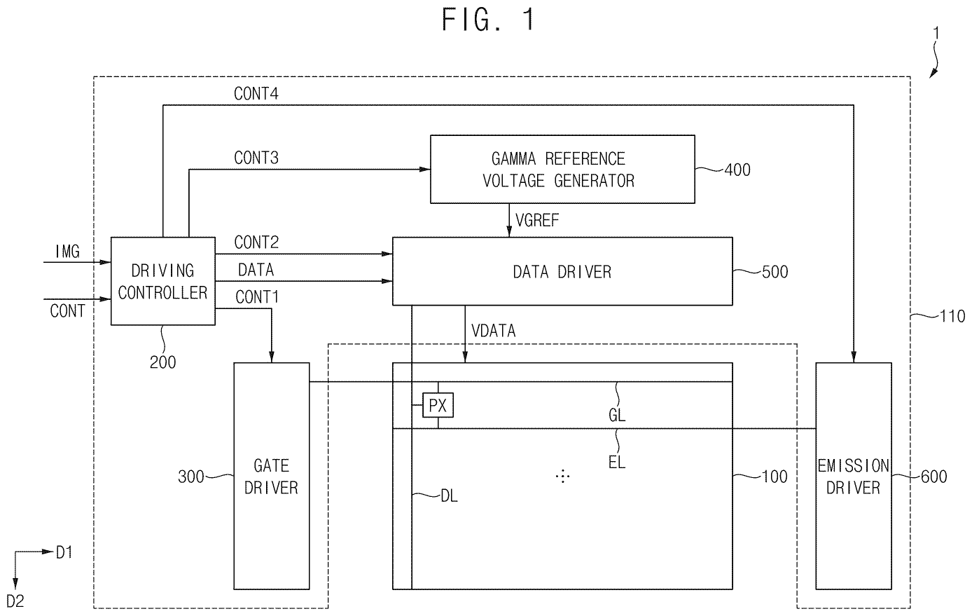

FIG. 1 is a block diagram illustrating a display device 1 according to embodiments of the present invention.

Referring to FIG. 1, an embodiment of the display device 1 may include a display panel 100 and a display panel driver 110. The display panel driver may include a driving controller 200, a gate driver 300, a gamma reference voltage generator 400, a data driver 500 and an emission driver 600.

The display panel 100 may include a display region on which an image is displayed and a peripheral region adjacent to the display region.

The display panel 100 may include a plurality of gate lines GL, plurality of emission lines EL, a plurality of data lines DL and a plurality of pixels electrically connected to the gate lines GL, the emission lines EL and the data lines DL. The gate lines GL may extend in a first direction D1, the emission lines EL may extend in the first direction D1 and the data lines DL may extend in a second direction D2 crossing the first direction D1.

The driving controller 200 may receive input image data IMG and an input control signal CONT from an external apparatus. In an embodiment, for example, the input image data IMG may include red image data, green image data and blue image data. The input image data IMG may include white image data. The input image data IMG may include magenta image data, cyan image data and yellow image data. The input control signal CONT may include a master clock signal and a data enable signal. The input control signal CONT may further include a vertical synchronizing signal and a horizontal synchronizing signal.

The driving controller 200 may generate a first control signal CONT1, a second control signal CONT2, a third control signal CONT3, a fourth control signal CONT4 and a data signal DATA based on the input image data IMG and the input control signal CONT.

The driving controller 200 may generate the first control signal CONT1 for controlling an operation of the gate driver 300 based on the input control signal CONT, and output the first control signal CONT1 to the gate driver 300. The first control signal CONT1 may include a vertical start signal and a gate clock signal.

The driving controller 200 may generate the second control signal CONT2 for controlling an operation of the data driver 500 based on the input control signal CONT, and outputs the second control signal CONT2 to the data driver 500. The second control signal CONT2 may include a horizontal start signal and a load signal.

The driving controller 200 may generate the data signal DATA based on the input image data IMG. The driving controller 200 may output the data signal DATA to the data driver 500.

The driving controller 200 may generate the third control signal CONT3 for controlling an operation of the gamma reference voltage generator 400 based on the input control signal CONT, and output the third control signal CONT3 to the gamma reference voltage generator 400.

The driving controller 200 may generate the fourth control signal CONT4 for controlling an operation of the emission driver 600 based on the input control signal CONT, and output the fourth control signal CONT4 to the emission driver 600.

The gate driver 300 may generate gate signals driving the gate lines GL in response to the first control signal CONT1 received from the driving controller 200. The gate driver 300 may output the gate signals to the gate lines GL.

In an embodiment, the gate driver 300 may be disposed in the peripheral region. In an embodiment, the gate driver 300 may be integrated in the peripheral region.

The gamma reference voltage generator 400 may generate a gamma reference voltage VGREF in response to the third control signal CONT3 received from the driving controller 200. The gamma reference voltage generator 400 may provide the gamma reference voltage VGREF to the data driver 500. The gamma reference voltage VGREF may have a value corresponding to a level of the data signal DATA.

In an embodiment, the gamma reference voltage generator 400 may be disposed in the driving controller 200, or in the data driver 500.

The data driver 500 may receive the second control signal CONT2 and the data signal DATA from the driving controller 200, and receive the gamma reference voltages VGREF from the gamma reference voltage generator 400. The data driver 500 may convert the data signal DATA into data voltages VDATA having an analog type using the gamma reference voltages VGREF. The data driver 500 may output the data voltages VDATA to the data lines DL.

The emission driver 600 may generate emission signal in response to the fourth control signal CONT4 received from the driving controller 200. The emission driver 600 may output the emission signal to the display panel 100.

In an embodiment, the emission driver 600 may be disposed in the peripheral region. In an embodiment, the emission driver 600 may be integrated in the peripheral region.

Although an embodiment where the gate driver 300 is disposed on a first side of the display panel 100, and the emission driver 600 is disposed on a second side of the display panel 100 is shown in FIG. 1 for convenience of illustration and description, the invention is not limited thereto. In another embodiment, the gate driver 300 and the emission driver 600 may be disposed on the first side of the display panel 100. In an embodiment, for example, the gate driver 300 and the emission driver 600 may be disposed on the peripheral region of the display panel 100 on a same side of the display region of the display panel 100. In an embodiment, for example, the gate driver 300 and the emission driver 600 may be formed integrally with each other as a single chip.

In an embodiment, the display panel driver 110 may further include a stress convertor. The stress convertor may output a deterioration information of the display panel 100. In an embodiment, the stress convertor may be included in the driving controller 200.

For example, the stress convertor may determine the deterioration information based on the input image data IMG. In an embodiment, the stress convertor may generate the deterioration information based on the input image data IMG. For example, the deterioration information may refer to a value based on at least one of display luminance (e.g., brightness), temperature, current of the display panel 100 and voltage of the display panel 100. For example, the deterioration information may include information such as deterioration time and deterioration grayscale.

In an embodiment, the stress convertor may further include a volatile memory which accumulates and stores the calculated deterioration information. For example, the volatile memory may be RAM. For example, the volatile memory may be SRAM. However, the present invention is not limited to a type of volatile memory.

In an embodiment, the display device may further include a nonvolatile memory which accumulates and stores the deterioration information calculated by the stress convertor. For example, the nonvolatile memory may be a flash memory. However, the present invention is not limited to a type of the nonvolatile memory. In an embodiment, the nonvolatile memory may be included in the driving controller 200.

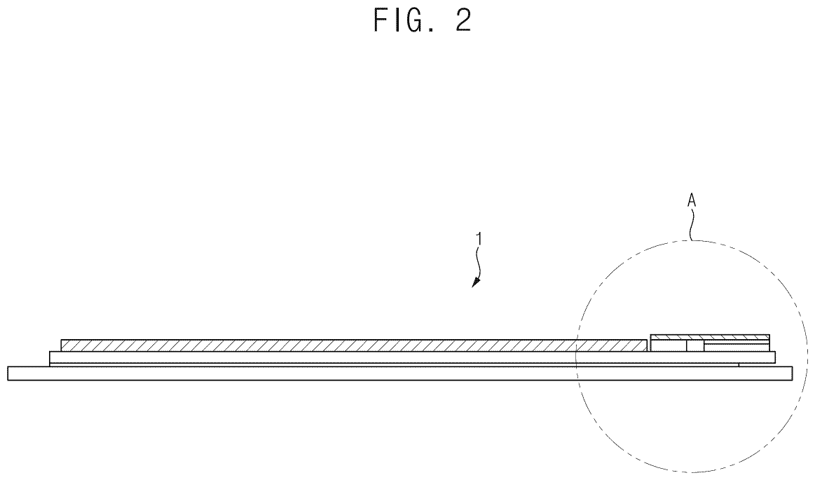

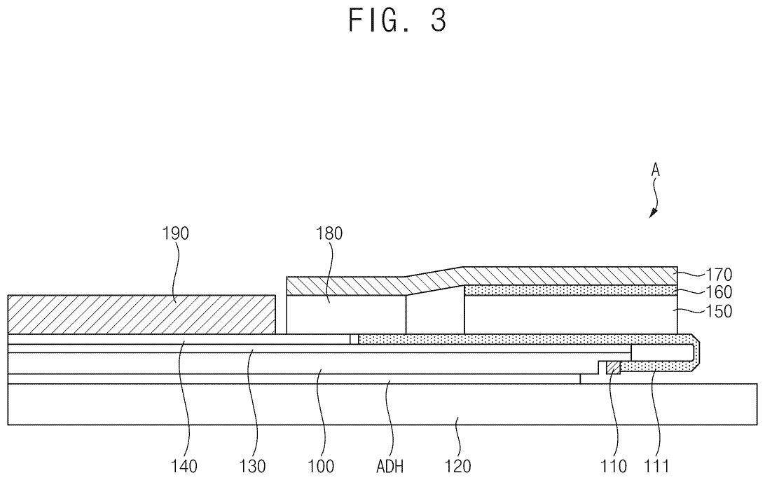

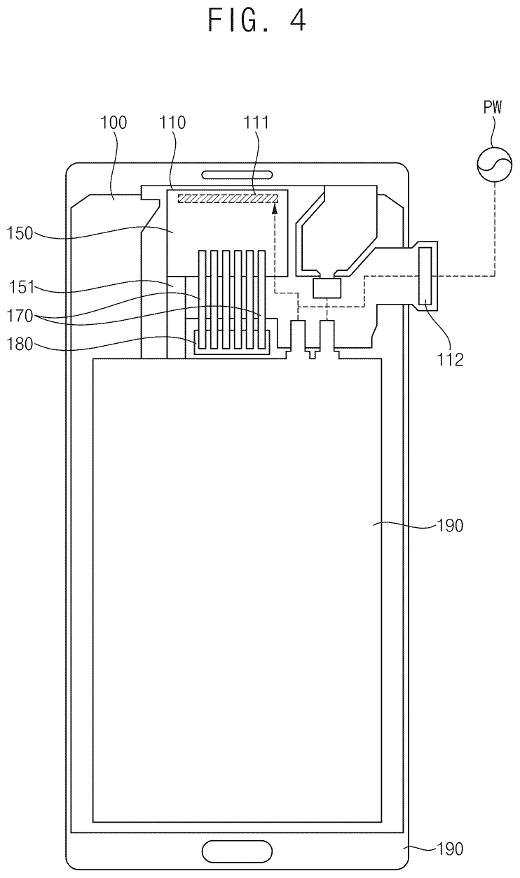

FIG. 2 is a side view illustrating an example of the display device 1 of FIG. 1. FIG. 3 is an enlarged view of area A of FIG. 2. FIG. 4 is a plan view illustrating an example of the display device 1 of FIG. 1. As used herein, the plan view is a view in a thickness direction of the display device.

Referring to FIG. 1 to FIG. 4, the display device 1 may include the display panel 100, the display panel driver 110, a printed circuit board 111 (or a flexible circuit board), a window 120 (or a window module), a cover sheet 130, a second heat dissipation sheet 140, a thermoelectric element 150 (e.g., a Peltier element, a Seebeck element), a first heat dissipation sheet 160, a heat pipe 170, an energy converting block 180, and an embedded battery 190.

The display panel driver 110 may be adjacent to one side of the display panel 100. The display panel driver 110 may be directly mounted on the display panel 100. In an embodiment, the display panel driver 110 may be mounted on the printed circuit board 111. The display panel driver 110 may be located on a lower surface (e.g., a second surface) of the display panel 100. In an embodiment, the display panel driver 110 may be located on an upper surface (e.g., a first surface) of the display panel 100 while being mounted on the printed circuit board 111.

The printed circuit board 111 may be located between the display panel 100 and the thermoelectric element 150. The printed circuit board 111 may be connected to the display panel 100 and the display panel driver 110. The printed circuit board 111 may connect at least two of the display panel 100, the display panel driver 110, the embedded battery 190 and an external power PW. The external power PW may refer to a power management integrated circuit PMIC for driving the display device 1.

One end portion of the printed circuit board 111 may be connected to one end of the display panel 100 and/or the display panel driver 110. The central portion of the printed circuit board 111 may be bent. The other end portion of the printed circuit board 111 may be located on the upper surface of the display panel 100. The display panel driver 110 may receive an external power PW through a first connector 112 and the printed circuit board 111. The display panel driver 110 may receive power from the embedded battery 190 through the printed circuit board 111. The embedded battery 190 may be charged by receiving power from the external power PW through the printed circuit board 111. The embedded battery 190 may supply power to the display panel driver 110.

In an embodiment, the printed circuit board 111 may electrically connect the energy converting block 180 and the embedded battery 190. In an embodiment, the printed circuit board 111 may connect the thermoelectric element 150 to the embedded battery 190. That is, the energy converting block 180 may supply power to the embedded battery 190 through the printed circuit board 111. The embedded battery 190 may supply power (or current) to the thermoelectric element 150 through the printed circuit board 111.

The window 120 may be provided under the display panel 100 and may be attached to the display panel 100 by an adhesive ADH. For example, the adhesive ADH may be an optically clear adhesive (“OCA”) or an optically clear resin (“OCR”). Materials of the window 120 may be glass, sapphire, plastic, etc. The window 120 may be of single or multiple layers. The window 120 may include a functional coated layer. The functional coated layer may include an anti-fingerprint layer, an anti-reflection layer, and a hard-coated layer.

The cover sheet 130 may be provided on the display panel 100 and may protect the top surface (i.e., the first surface) of the display panel 100.

The second heat dissipation sheet 140 may be located on the cover sheet 130. The second heat dissipation sheet 140 may dissipate the heat from the embedded battery 190 to the outside.

The thermoelectric element 150 may be located on the top surface of the display panel 100. The thermoelectric element 150 may overlap the display panel driver 110. The thermoelectric element 150 may be located to cover a part of the display panel 100 where the display panel driver 110 is located.

The thermoelectric element 150 may connect to the embedded battery 190 through a second connector 151. The thermoelectric element 150 may receive power from the embedded battery 190.

The thermoelectric element 150 may include a Peltier element which utilizes a Peltier effect. The Peltier effect may refer to a phenomenon of absorbing and dissipating the heat by electric current.

The thermoelectric element 150 may include a Seebeck element which utilizes a Seebeck effect. The Seebeck effect may refer to a phenomenon in which an electromotive force is generated due to a temperature difference.

A bottom surface (i.e., a second surface) of the thermoelectric element 150 may be a cooling section, and a top surface (i.e., a first surface opposite to the second surface) may be a heating section. When power (or current) is applied to the thermoelectric element 150 from the embedded battery 190, the bottom surface of the thermoelectric element 150 may absorbs the heat, and the top surface of the thermoelectric element 150 may dissipate the heat. Accordingly, the thermoelectric element 150 may quickly absorb heat generated by the display panel driver 110. Additionally, the thermoelectric element 150 may quickly cool the display panel driver 110.

In an embodiment, the thermoelectric element 150 may operate based on the temperature measured by a separate temperature sensor. For example, when the measured temperature is higher than a reference temperature, the embedded battery 190 may apply power (or, current) to the thermoelectric element 150. For example, when the measure temperature is lower than the reference temperature, the embedded battery 190 may stop applying the power (or, current) to the thermoelectric element 150.

The first heat dissipation sheet 160 (or a heat absorbing plate, or a heatsink) may be located on the top surface of the thermoelectric element 150. The first heat dissipation sheet 160 may be located between the thermoelectric element 150 and the heat pipe 170.

The first heat dissipation sheet 160 may quickly absorb the heat from the top surface of the thermoelectric element 150. The first heat dissipation sheet 160 may quickly dissipate the heat from the top surface of the thermoelectric element 150. The first heat dissipation sheet 160 may include the thermal interface material which has high thermal conductivity. The first heat dissipation sheet 160 may attach the thermoelectric element 150 and the heat pipe 170 to each other.

The heat pipe 170 may be located on the top surface of the display panel 100. The heat pipe 170 may overlap the thermoelectric element 150 and the energy converting block 180 in the plan view.

The heat pipe 170 may be located on the first heat dissipation sheet 160. Additionally, the heat pipe 170 may be located on the energy converting block 180. The heat pipe 170 may be connected to the energy converting block 180.

The heat pipe 170 may absorb heat from the thermoelectric element 150 through the first heat dissipation sheet 160. The heat pipe 170 may dissipate the absorbed heat to the energy converting block 180.

The energy converting block 180 may be located on the top surface of the display panel 100. The energy converting block 180 may be located between the thermoelectric element 150 and the embedded battery 190.

The energy converting block 180 may convert heat (e.g., thermal energy) dissipated from the heat pipe 170 into electrical energy. The energy converting block 180 may output the electrical energy to the embedded battery 190.

The energy converting block 180 may generate electrical energy using the Seebeck effect. The energy converting block 180 may determine a voltage corresponding to the dissipated heat using the Seebeck effect. The energy converting block 180 may determine the voltage corresponding to the temperature difference using the Seebeck effect. For example, the voltage corresponding to the dissipated heat may be referred to as a generation voltage. For example, the generation voltage may mean the voltage corresponding to the temperature difference.

For example, when a temperature of the display panel driver 110 changes from a first temperature to a second temperature, a first generation voltage corresponding to the temperature difference between the first temperature and the second temperature may be generated based on the Seebeck effect. The energy converting block 180 may determine a voltage level of the first generated voltage.

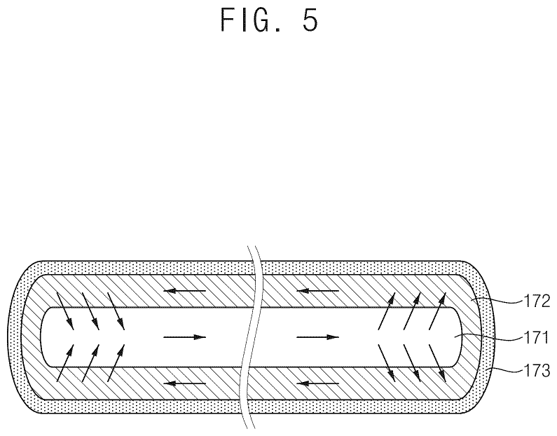

FIG. 5 is a diagram illustrating an example of a heat pipe 170 included in the display device 1 of FIG. 2.

Referring to FIG. 1 to FIG. 5, the heat pipe 170 may include a vapor cavity 171, a wick 172, and a thermal conductor 173.

The vapor cavity 171 may change the phase of a working fluid (i.e., refrigerant) therein from liquid to gas using the absorbed heat from the thermoelectric element 150 through the first heat dissipation sheet 160. The heat may be delivered along the vapor cavity 171 to the energy converting block 180. The wick 172 may surround the vapor cavity 171 and change the phase of the working fluid from gas to liquid by using the dissipated heat from the energy converting block 180. The heat may be delivered back to the thermoelectric element 150 along the wick 172. The thermal conductor 173 may be a material with high thermal conductivity. The thermal conductor 173 may surround the wick 172. The thermal conductor 173 may include or is formed of a material of high thermal conductivity, for example, gold (Au), carbon (C), or graphite, etc.

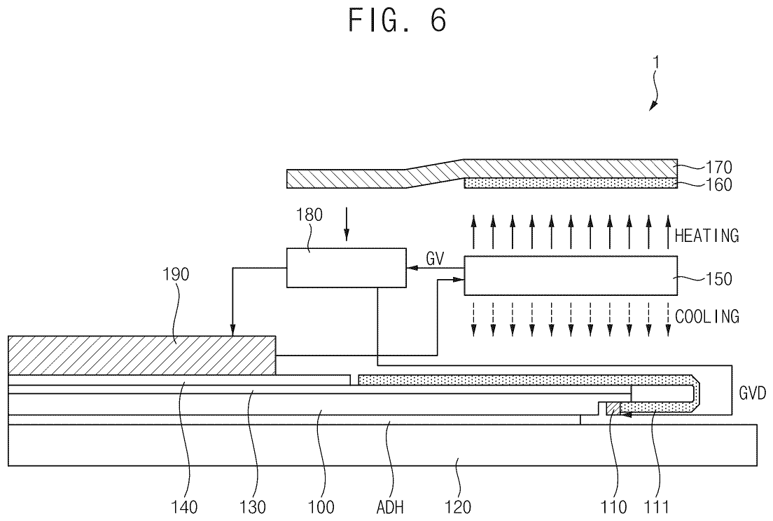

FIG. 6 is a diagram illustrating an energy flow of a display device 1 of FIG. 2.

Referring to FIG. 1 to FIG. 6, the display panel driver 110 may produce heat as a heat source. Some of the heat dissipated from the display panel driver 110 may be dissipated through the window 120 to the outside.

The heat dissipated from the display panel driver 110 may be delivered to the thermoelectric element 150 through the printed circuit board 111. The heat may be delivered to the thermoelectric element 150 through the printed circuit board 111.

As a cooling section, the bottom surface of the thermoelectric element 150 may absorb heat. The thermoelectric element 150 may cool the printed circuit board 111 and the display panel driver 110. Additionally, as a heating section, the top surface of the thermoelectric element 150 may dissipate heat.

The heat dissipated from the top surface of the thermoelectric element 150 may be absorbed through the first heat dissipation sheet 160. The heat dissipated from the top surface of the thermoelectric element 150 may be delivered to the heating section (i.e., a part where contacts the first heat dissipation sheet 160) of the heat pipe 170 through the first heat dissipation sheet 160. The heat dissipated from the top surface of the thermoelectric element 150 may be diffused to the heating section (i.e., a part where contacts the first heat dissipation sheet 160) of the heat pipe 170 through the first heat dissipation sheet 160.

The heat delivered to the heat pipe 170 may be delivered to the energy converting block 180 through the phase change of the working fluid (i.e., a refrigerant) according to the structure of the heat pipe 170.

The heat (i.e., thermal energy) delivered to the energy converting block 180 may be converted to electric energy by the energy converting block 180. The converted electric energy may be supplied to the embedded battery 190.

The embedded battery 190 may supply the power to the thermoelectric element 150, using the electric energy. Some of the heat generated by operations of the thermoelectric element 150 may be circulated through the first heat dissipation sheet 160, the heat pipe 170, and the energy converting block 180.

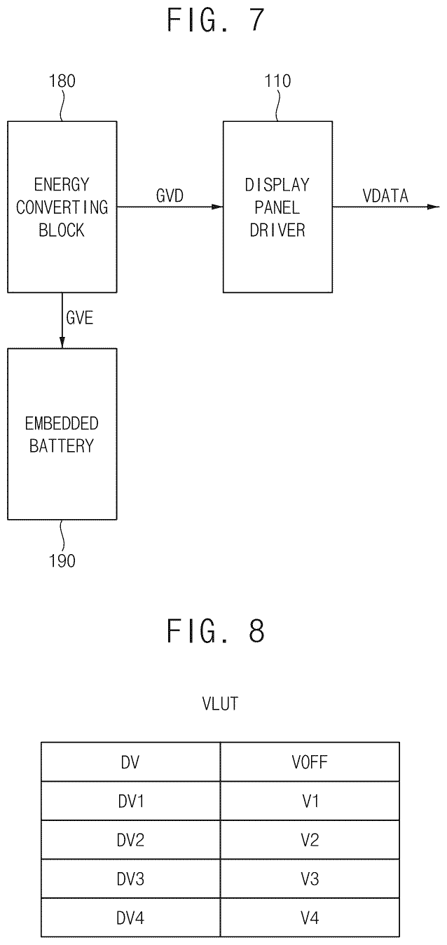

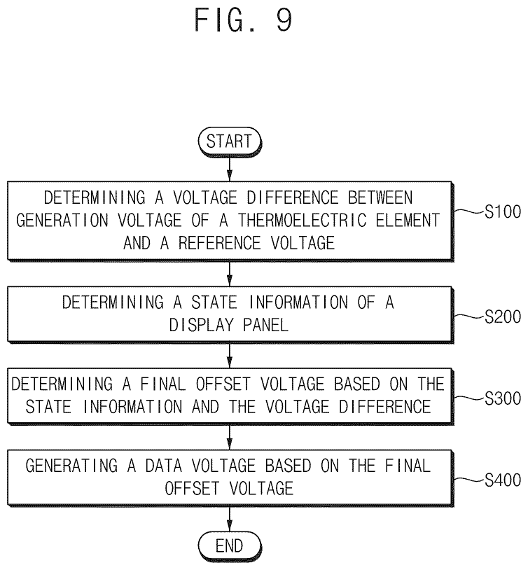

FIG. 7 is a block diagram illustrating an example of a display panel driver 110, an energy converting block 180 and an embedded battery 190 included in the display device 1 of FIG. 2. FIG. 8 is a table illustrating an example of a generation voltage lookup table VLUT stored in a display panel driver 110 of FIG. 7.

Referring to FIG. 1 to FIG. 8, the energy converting block 180 may determine the generation voltage GV corresponding to the dissipated heat using the Seebeck effect. The energy converting block 180 may determine the generation voltage GV corresponding to the temperature difference using the Seebeck effect. The thermoelectric element 150 may generate the generation voltage GV based on the temperature difference of the thermoelectric element 150. The Electrical energy GVE may be generated based on the generation voltage GV. The energy converting block 180 may output the electrical energy GVE based on the generation voltage GV to the embedded battery 190.

The energy converting block 180 may output generation voltage data GVD corresponding to the generation voltage GV to the display panel driver 110. For example, when the temperature of the thermoelectric element 150 changes from a first temperature to a second temperature, a first generation voltage corresponding to the temperature difference may be generated. The energy converting block 180 may determine the first generation voltage. The energy converting block 180 may output the first generation voltage data corresponding to the first generation voltage to the display panel driver 110. For example, when the temperature of the thermoelectric element 150 changes from the second temperature to a third temperature, a second generation voltage corresponding to the temperature difference may be generated. The energy converting block 180 may determine the second generation voltage. The energy converting block 180 may output the second generation voltage data corresponding to the second generation voltage to the display panel driver 110.

The display panel driver 110 may receive the generation voltage data GVD. The display panel driver 110 may determine a voltage difference DV between the generation voltage GV corresponding to the generation voltage data GVD and a reference voltage. The display panel driver 110 may determine the generation voltage offset voltage VOFF based on the voltage difference DV between the generation voltage GV and the reference voltage.

For example, the display panel driver 110 may determine the generation voltage offset voltage VOFF based on the generation voltage lookup table VLUT. The generation voltage lookup table VLUT may include a plurality of generation voltage offset voltages. The generation voltage lookup table VLUT may include a generation voltage offset voltage corresponding to the voltage difference. In an embodiment, the generation voltage lookup table VLUT may be stored in the manufacturing process of the display device 1.

For example, the first generation voltage may be generated based on the first temperature difference of the thermoelectric element 150. When the first generation voltage is generated, the display panel driver 110 may receive first generation voltage data corresponding to the first generation voltage. A voltage difference between the first generation voltage and the reference voltage may be a first voltage difference DV1. The display panel driver 110 may determine a first generation voltage offset voltage V1 corresponding to the first voltage difference DV1.

For example, a second generation voltage may be generated based on a second temperature difference of the thermoelectric element 150. When the second generation voltage is generated, the display panel driver 110 may receive second generation voltage data corresponding to the second generation voltage. A voltage difference between the second generation voltage and the reference voltage may be a second voltage difference DV2. The display panel driver 110 may determine a second generation voltage offset voltage V2 corresponding to the second voltage difference DV2.

For example, a third generation voltage may be generated based on a third temperature difference of the thermoelectric element 150. When the third generation voltage is generated, the display panel driver 110 may receive third generation voltage data corresponding to the third generation voltage. A voltage difference between the third generation voltage and the reference voltage may be a third voltage difference DV3. The display panel driver 110 may determine a third generation voltage offset voltage V3 corresponding to the third voltage difference DV3.

For example, a fourth generation voltage may be generated based on a fourth temperature difference of the thermoelectric element 150. When the fourth generation voltage is generated, the display panel driver 110 may receive fourth generation voltage data corresponding to the fourth generation voltage. A voltage difference between the fourth generation voltage and the reference voltage may be a fourth voltage difference DV4. The display panel driver 110 may determine a fourth generation voltage offset voltage V4 corresponding to the fourth voltage difference DV4.

The display panel driver 110 may generate the data voltage VDATA based on the generation voltage offset voltage VOFF. The display panel driver 110 may generate the data voltage VDATA based on a grayscale data voltage corresponding to the input image data IMG and the generation voltage offset voltage VOFF.

For example, the display panel driver 110 may receive the input image data IMG corresponding to the first grayscale. When the display panel driver 110 receives the input image data IMG corresponding to the first grayscale, the display panel driver 110 may determine a first grayscale data voltage corresponding to the first grayscale. The display panel driver 110 may generate the data voltage VDATA based on the first grayscale data voltage and the generation voltage offset voltage VOFF. For example, a voltage level of the data voltage VDATA may have a value which is a sum of a voltage level of the first grayscale data voltage and a voltage level of the generation voltage offset voltage VOFF.

In the present embodiment, the generation voltage offset voltage VOFF may be considered to the data voltage VDATA in which the display panel driver 110 outputs. The generation voltage offset voltage VOFF may be determined based on the generation voltage GV. Additionally, the generation voltage GV may be generated based on the temperature difference of the thermoelectric element 150. The temperature difference of the thermoelectric element 150 may be generated based on the temperature change of the display panel driver 110. Accordingly, the temperature change of the display panel driver 110 may be considered to the data voltage VDATA. Since the temperature change of the display panel driver 110 may be considered to the data voltage VDATA, a display quality of the display panel 100 may be effectively improved.

In an embodiment, the display panel driver 110 may generate a data voltage based on a final offset voltage in which a state offset voltage corresponding to state information of the display panel and the generation voltage offset voltage VOFF is considered. For example, the state information may include a setting brightness of the display panel 100, a driving frequency of the display panel 100 or the deterioration information of the display panel 100. The state offset voltage may include a setting brightness offset voltage, a driving frequency offset voltage or a deterioration information offset voltage. The setting brightness offset voltage may refer to an offset voltage determined based on a change in the setting brightness of the display panel 100. The setting brightness offset voltage may be determined based on a setting brightness lookup table. The driving frequency offset voltage may refer to an offset voltage determined based on a change in the driving frequency of the display panel 100. The driving frequency offset voltage may be determined based on a driving frequency lookup table. The deterioration information offset voltage may refer to an offset voltage determined based on the deterioration information of the display panel 100. The deterioration information offset voltage may be determined based on a deterioration information lookup table. The state offset voltage may have a voltage level based on the setting brightness offset voltage, the driving frequency offset voltage and the deterioration information offset voltage.

In an embodiment, the state offset voltage and the generation voltage offset voltage VOFF may be considered to the data voltage VDATA in which the display panel driver 110 outputs. Accordingly, the state information of the display panel 100 may be considered to the data voltage VDATA. Additionally, the temperature change of the display panel driver 110 may be considered to the data voltage VDATA. Accordingly, the display quality of the display panel 100 may be further improved.

In an embodiment, the final offset voltage may be calculated based on a following first equation:

FVOFF=aX1+bX2+c. The first equation

In an embodiment, the final offset voltage may be calculated based on a following second equation:

FVOFF=aX1²+bX2+c. The second equation

In an embodiment, the final offset voltage is calculated based on a following third equation:

FVOFF=aX1+bX2²+c. The third equation

In an embodiment, the final offset voltage is calculated based on a following fourth equation:

FVOFF=aX1²+bX2+c. The fourth equation

Herein, FVOFF refers to the final offset voltage, a refers to a first constant, X1 refers to the state offset voltage, b refers to a second constant, X2 refers to the generation voltage offset voltage and c refers to a third constant. The first constant, the second constant and the third constant may be set in consideration of characteristics (e.g., size, physical properties, etc.) of the display device 1.

In an embodiment, the reference voltage may be changed based on an environmental fact. For example, the environmental fact may refer to the ambient temperature. For example, the reference voltage may be changed in real time.

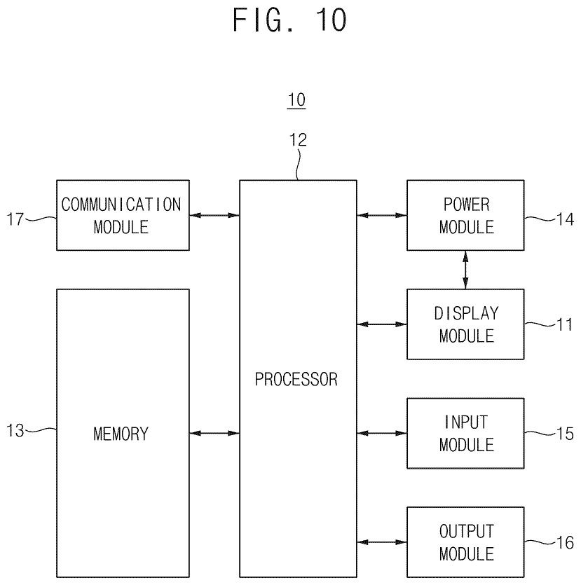

FIG. 9 is a flowchart illustrating an example of a method by which the display panel driver 110 of FIG. 7 generates a data voltage VDATA.

Referring to FIG. 1 to FIG. 9, the display panel driver 110 may determine the voltage difference between the generation voltage GV of the thermoelectric element 150 and the reference voltage. (S100) The display panel driver 110 may determine the state information of the display panel 100. (S200) The display panel driver 110 may determine the final offset voltage based on the state information and the voltage difference. (S300) The display panel driver 110 may generate the data voltage VDATA based on the final offset voltage. (S400)

In an embodiment, when the voltage difference between the generation voltage GV of the thermoelectric element 150 and the reference voltage is not 0 (for example, when the voltage level of the generation voltage GV is different from the voltage level of the reference voltage), the display panel driver 110 may determine the generation voltage offset voltage VOFF again. For example, in an embodiment, when the voltage difference between the generation voltage GV of the thermoelectric element 150 and the reference voltage is not 0 (for example, when the voltage level of the generation voltage GV is different from the voltage level of the reference voltage), the display panel driver 110 may consider the generation voltage offset voltage VOFF in the final offset voltage.

In an embodiment, when the voltage difference between the generation voltage GV of the thermoelectric element 150 and the reference voltage is 0 (e.g., when the voltage level of the generation voltage GV and the voltage level of the reference voltage are the same), the display panel driver 110 may not determine the generated voltage offset voltage VOFF. For example, in an embodiment, when the voltage difference between the generation voltage GV of the thermoelectric element 150 and the reference voltage is 0 (e.g., when the voltage level of the generation voltage GV and the voltage level of the reference voltage are the same), the generation voltage offset voltage VOFF may be 0. For example, in an embodiment, when the voltage difference between the generation voltage GV of the thermoelectric element 150 and the reference voltage is 0 (e.g., when the voltage level of the generation voltage GV and the voltage level of the reference voltage are the same), the generation voltage offset voltage VOFF may not be considered in the final offset voltage.

In the present embodiment, the generation voltage offset voltage VOFF may be considered to the data voltage VDATA in which the display panel driver 110 outputs. The generation voltage offset voltage VOFF may be determined based on the generation voltage GV. Additionally, the generation voltage GV may be generated based on the temperature difference of the thermoelectric element 150. The temperature difference of the thermoelectric element 150 may be generated based on the temperature change of the display panel driver 110. Accordingly, the temperature change of the display panel driver 110 may be considered to the data voltage VDATA. Since the temperature change of the display panel driver 110 may be considered to the data voltage VDATA, the display quality of the display panel 100 may be effectively improved.

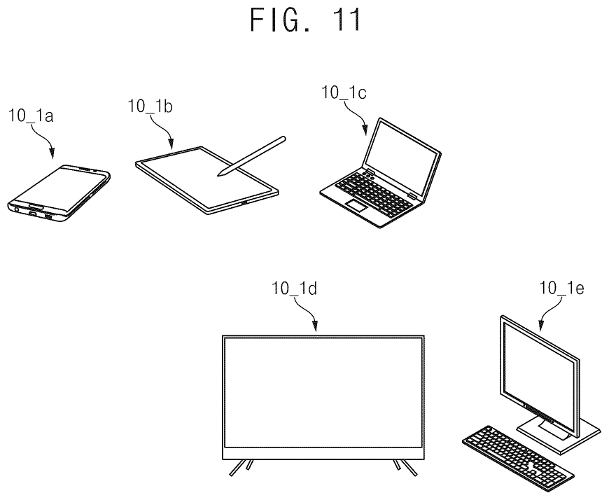

FIG. 10 is a block diagram illustrating an electronic device 10 according to embodiments of the present invention.

Referring to FIG. 12, an electronic device 10 according to an embodiment may include a display module 11, a processor 12, a memory 13 and a power module 14.

The processor 12 may include at least one of a central processing unit (CPU), an application processor (AP), a graphic processing unit (GPU), a communication processor (CP), an image signal processor (ISP), and a controller. The processor 12 may output the input control signal CONT of FIG. 1.

The memory 13 may store data information necessary for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module which converts power supplied by the power supply module to generate power required for the operation of the electronic device 10.

The electronic device 10 may further include an input module 15, a non-image output module 16 and/or a communication module 17.

The input module 15 may provide input information to the processor 12 and/or the display module 11. The input module 15 may include various sensor modules as well as physical buttons, a keyboard, and a microphone. Examples of the sensor modules may include a touch sensor, a pressure sensor, a distance sensor, a position sensor, a digitizer, a motion recognition sensor, a camera sensor, a light receiving sensor, a photoelectric conversion sensor, a temperature sensor, and a biosensor such as a blood pressure sensor, a blood sugar sensor, an electrocardiogram sensor, and a heart rate sensor.

The non-image output module 16 may receive information other than images from the processor 12 and provide the information to the user. Examples of the non-image output module 16 may include an audio module, a haptic module, a light-emitting module, etc., and may include other functional modules unique to electronic devices (e.g., a cooling module of a refrigerator, etc.).

The communication module 17 may be a module that is responsible for transmitting and receiving information between the electronic device 10 and an external device, and may include a receiving unit and a transmitting unit. The communication module 17 may include various wireless communication modules such as a mobile communication module, a Wi-Fi module, a Bluetooth module, or various wired communication modules.

At least one of the components of the electronic device 10 described above may be included in the display device according to the embodiments described above. Additionally, some of the individual modules functionally included in one module may be included in the display device, and other may be provided separately from the display device. For example, the display device may include the display module 11, and the processor 12, the memory 13, and the power module 14 may be provided in the form of other devices within the electronic device 10 other than the display device.

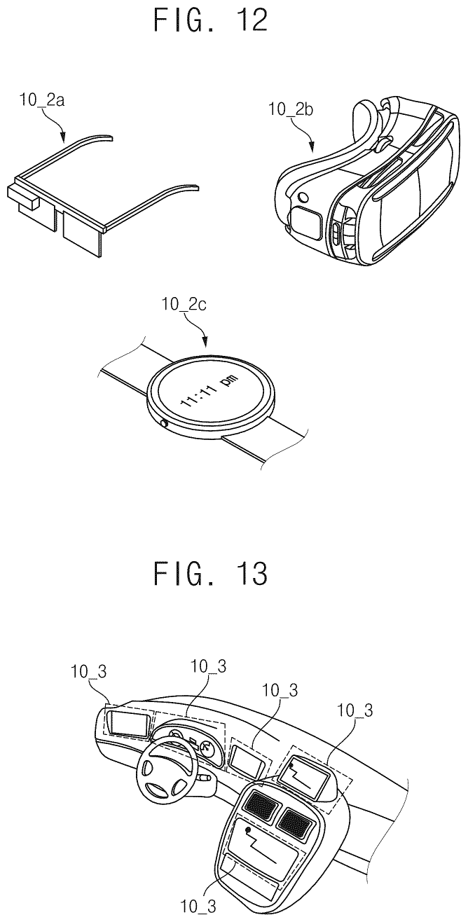

FIG. 11 to FIG. 13 are schematic diagrams illustrating an electronic device according to embodiments.

Referring to FIG. 11, a smartphone 10_1a, a tablet PC 10_1b, a laptop 10_1c, a TV 10_1d, and a desk monitor 10_1e are examples of electronic devices.

The smartphone 10_1a may include an input module such as a touch sensor and a communication module in addition to the display module 11. The smartphone 10_1a may process information received through the communication module or other input modules and display the information through the display module of the display device.

In the case of tablet PC 10_1b, laptop 10_1c, TV 10_1d, and desk monitor 10_1e, may include a display module and an input module similar to the smartphone 10_1a, and in some cases, may further include a communication module.

Referring to FIG. 12, an electronic device including a display module may be applied to a wearable electronic device. The wearable electronic device may be a smart glasses 10_2a, a head mounted display 10_2b, a smart watch 10_2c, etc.

The smart glasses 10_2a and head mounted displays 10_2b may include a display module which emits a display image and a reflector which reflects the emitted display image and provides it to the user's eyes, thereby providing a virtual reality or augmented reality screen to the user.

The smartwatch 10_2c may include a biometric sensor as an input device and may provide biometric information recognized by the biometric sensor to the user through a display module.

Referring to FIG. 13, an electronic device including a display module may be applied to a vehicle. For example, the electronic device 10_3 may be applied to a dashboard, center fascia, etc. of a vehicle, or may be applied to a CID (Center Information Display) placed on a dashboard of a vehicle or a room mirror display replacing a side mirror.

Although not illustrated, electronic devices to which the display device according to the embodiments is applied may include not only devices that mainly display screens, such as billboards, electronic boards, and game consoles, but also various home appliances that display information through display modules, such as refrigerators, washing machines, dryers, air conditioners, and robot vacuum cleaners. Additionally, when the display module has a function of transmitting light, it may be applied to electronic devices, such as smart windows or transparent display devices that display a background and a display image together. The type of electronic device according to the embodiment is not limited by the examples, and application to other various electronic devices that are not illustrated may also be possible.

The display device according to the embodiments may be applied to a display device included in a computer, a notebook, a mobile phone, a smart phone, a smart pad, a PMP, a PDA, an MP3 player, or the like.

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A display device comprising:
a display panel, which displays an image;
a display panel driver, which drives the display panel;
a thermoelectric element located on a first surface of the display panel and which overlaps the display panel driver; and
an energy converting block, which generates an electric energy based on a temperature difference of the thermoelectric element,
wherein the energy converting block determines a first voltage corresponding to the temperature difference of the thermoelectric element,
wherein the energy converting block outputs generation voltage data corresponding to the first voltage, and
wherein the display panel driver generates a data voltage which is applied to the display panel based on the generation voltage data.

2. The display device of claim 1, wherein the data voltage is generated based on a generation voltage offset voltage, and
wherein the generation voltage offset voltage is determined based on a voltage level difference between the first voltage and a reference voltage.

3. The display device of claim 2, wherein the generation voltage offset voltage is determined based on a generation voltage lookup table,
each of the generation voltage offset voltage and the voltage level difference is provided in plurality, and
wherein the generation voltage lookup table includes the voltage level differences and the generation voltage offset voltages corresponding to the voltage level differences, respectively.

4. The display device of claim 2, wherein the data voltage is generated based on a final offset voltage based on both a state offset voltage corresponding to a state information of the display panel and the generation voltage offset voltage.

5. The display device of claim 4, wherein the state information includes a setting brightness of the display panel, a driving frequency of the display panel or a deterioration information of the display panel.

6. The display device of claim 4, wherein the final offset voltage is calculated based on a following first equation:
FVOFF=aX1+bX2+c, (first equation)
wherein FVOFF refers to the final offset voltage, a refers to a first constant, X1 refers to the state offset voltage, b refers to a second constant, X2 refers to the generation voltage offset voltage and c refers to a third constant.

7. The display device of claim 4, wherein the final offset voltage is calculated based on a following second equation:
FVOFF=aX1+bX2+c, (second equation)
wherein FVOFF refers to the final offset voltage, a refers to a first constant, X1 refers to the state offset voltage, b refers to a second constant, X2 refers to the generation voltage offset voltage and c refers to a third constant.

8. The display device of claim 4, wherein the final offset voltage is calculated based on a following third equation:
FVOFF=aX1+bX2²+c, (third equation)
wherein FVOFF refers to the final offset voltage, a refers to a first constant, X1 refers to the state offset voltage, b refers to a second constant, X2 refers to the generation voltage offset voltage and c refers to a third constant.

9. The display device of claim 4, wherein the final offset voltage is calculated based on a following fourth equation:
FVOFF=aX1²+bX2²+c, (fourth equation)
wherein FVOFF refers to the final offset voltage, a refers to a first constant, X1 refers to the state offset voltage, b refers to a second constant, X2 refers to the generation voltage offset voltage and c refers to a third constant.

10. The display device of claim 2, wherein the reference voltage is changed based on an environmental fact.

11. The display device of claim 1, wherein the first voltage is determined based on a Seeback effect of the thermoelectric element.

12. A display device comprising:
a display panel, which displays an image;
a display panel driver, which drives the display panel;
a thermoelectric element, which controls a temperature of the display panel; and
an energy converting block, which determines a generation voltage corresponding to the temperature of the display panel,
wherein the energy converting block outputs generation voltage data corresponding to the generation voltage, and
wherein the display panel driver generates a data voltage which is applied to the display panel based on the generation voltage data.

13. The display device of claim 12, wherein the generation voltage is determined based on a Seeback effect of the thermoelectric element.

14. The display device of claim 12, wherein the data voltage is generated based on a generation voltage offset voltage, and
wherein the generation voltage offset voltage is determined based on a voltage level difference between the generation voltage and a reference voltage.

15. The display device of claim 14, wherein the data voltage is generated based on a final offset voltage based on both a state offset voltage corresponding to a state information of the display panel and the generation voltage offset voltage.

16. The display device of claim 15, wherein the state information includes setting brightness of the display panel, a driving frequency of the display panel or a deterioration information of the display panel.

17. An electronic device comprising:
a display panel, which displays an image;
a display panel driver, which drives the display panel based on an input control signal;
a processor, which outputs the input control signal;
a thermoelectric element located on a first surface of the display panel and which overlaps the display panel driver; and
an energy converting block, which generates an electric energy based on a temperature difference of the thermoelectric element,
wherein the energy converting block determines a first voltage corresponding to the temperature difference of the thermoelectric element,
wherein the energy converting block outputs generation voltage data corresponding to the first voltage, and
wherein the display panel driver generates a data voltage which is applied to the display panel based on the generation voltage data.

18. The electronic device of claim 17, wherein the data voltage is generated based on a generation voltage offset voltage, and
wherein the generation voltage offset voltage is determined based on a voltage level difference between the first voltage and a reference voltage.

19. The electronic device of claim 18, wherein the data voltage is generated based on a final offset voltage based on both a state offset voltage corresponding to a state information of the display panel and the generation voltage offset voltage.

20. The electronic device of claim 17, wherein the first voltage is determined based on a Seeback effect of the thermoelectric element.
